(19) United States
(12) Patent Application Publication
(10) Pub. No.: US 2026/0279434 A1
(43) Pub. Date: Sep. 17, 2026

(54) GLOBAL FUNCTIONAL MODULE, SEMICONDUCTOR DEVICE COMPRISING THE SAME, AND METHOD FOR FABRICATING THE SAME

(71) Applicant: NANYA TECHNOLOGY CORPORATION, NEW TAIPEI CITY (TW)

(72) Inventor: PIN-HSIU HSIEH, NEW TAIPEI CITY (TW)

(21) Appl. No.: 19/077,277

(22) Filed: Mar. 12, 2025

(51) Int. Cl. G11C 11/413

(52) U.S. Cl. CPC G11C 11/413

(57) ABSTRACT

The present application discloses a global functional module, a semiconductor device including the global functional module, and a method for fabricating the semiconductor device with the global functional module. The global functional module includes a plurality of first-type interface sub-modules and at least two second-type sub-modules communicated with the plurality of first-type interface sub-modules.

### TECHNICAL FIELD

The present disclosure relates to a global functional module, a semiconductor device comprising the global functional module, and a method for fabricating the semiconductor device comprising the global functional module.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a global functional module including a plurality of first-type interface sub-modules; and at least two second-type sub-modules communicated with the plurality of first-type interface sub-modules.

Another aspect of the present disclosure provides a semiconductor device including a plurality of storage modules; a global functional module comprising a plurality of first-type interface sub-modules configured to interface with the plurality of storage modules, and at least two second-type sub-modules communicated with the plurality of first-type interface sub-modules and configured to interface with an external logic module.

Another aspect of the present disclosure provides a method for fabricating a semiconductor device including providing an external logic module; providing a plurality of storage modules; providing a global functional module comprising a plurality of first-type interface sub-modules, and at least two second-type sub-modules communicated with the plurality of first-type interface sub-modules; packaging the plurality of storage modules, the global functional module, and the external logic module. The plurality of first-type interface sub-modules interface with the plurality of storage modules. One of the at least two second-type sub-modules interfaces with the external logic module.

Due to the design of the semiconductor device of the present disclosure, the global functional module and the storage module integrate storage and logic functionalities in a modular and reconfigurable manner, providing flexibility in product design and reducing development time.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 9 illustrate, in schematic block diagrams, semiconductor devices in accordance with some embodiments of the present disclosure; and

FIG. 10 illustrates, in a flowchart diagram form, a method for fabricating a semiconductor device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

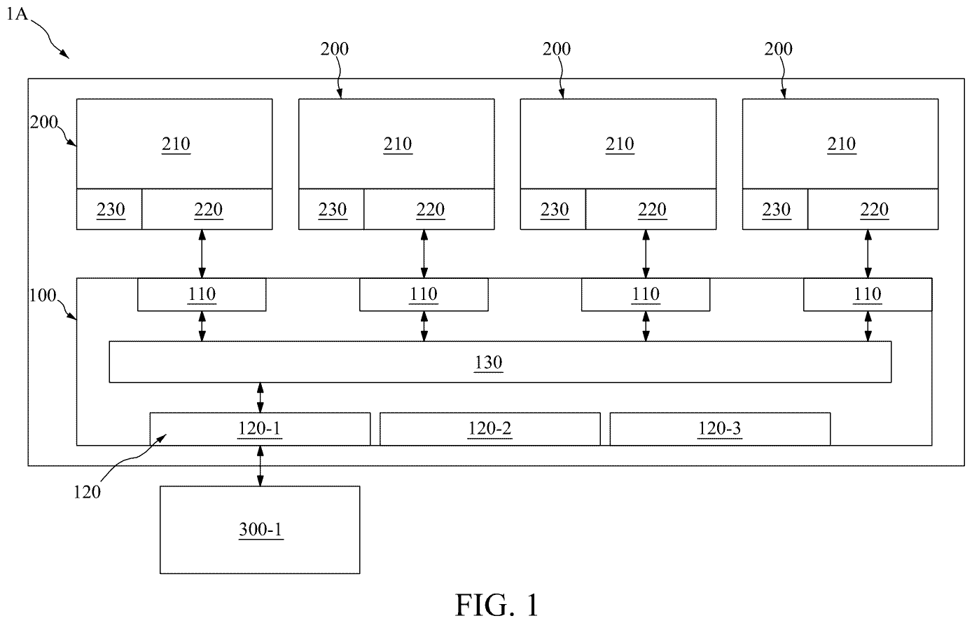

FIGS. 1 to 9 illustrate, in schematic block diagrams, semiconductor devices 1A, 1B, 1C, 1D, 1E, 1F, 1G, 1H, and 1I in accordance with some embodiments of the present disclosure.

It should be noted that the double-sided arrow line indicates the presence of electrical or signal connections between two features.

In the present disclosure, a semiconductor device may combine storage and logic functionalities in a modular and reconfigurable manner.

With reference to FIG. 1, the semiconductor device 1A may include a storage portion and a logic peripheral portion. In some embodiments, the storage portion may include a plurality of storage modules 200 that are responsible for data storage. Each storage module 200 may include a storage array 210 including capacitors or non-volatile memory units for actual data storage, a local interface sub-module 220 that provides the electrical/signal connection to the logic peripheral portion, and a plurality of functional sub-modules 230 that provide essential functions (e.g., decoding, multiplexer, buffering, repair, and/or refresh management).

The logic peripheral portion may be responsible for handling external interfacing, data flow management (or data streaming management), and system-level control. In some embodiments, the logic peripheral portion may include a global functional module 100 and may include a plurality of first-type interface sub-modules 110, at least two second-type sub-modules 120, and a global functional sub-module 130.

The plurality of first-type interface sub-modules 110 may be designed with a uniform layout to interface reliably with the local interface sub-modules 220 of the plurality of storage modules 200, respectively and correspondingly. Their uniformity may ensure consistent signal integrity and predictable timing.

The at least two second-type sub-modules 120 may be configured to interface with external logic modules. All the second-type sub-modules 120 may have different designs to interface with different external logic modules. The second-type sub-modules 120 with different designs may be respectively notated as the second-type sub-module 120-1, the second-type sub-module 120-2, and the second-type sub-module 120-3 in the present disclosure. Although multiple second-type sub-modules 120 are provided, only one of the second-type sub-module 120 is enabled at any given time, while the others remain disabled. This approach allows a single global functional module 100 to support multiple interface standards and various designs.

The global functional sub-module 130 may provide data streaming management in order to remap the data sequence ordering, data burst length, data line width between the first-type interface sub-modules 110 and the second-type sub-modules 120. The dynamic data flow management functions of the global functional sub-module 130 may enable the scalable capability for the plurality of storage modules 200 and the flexibility for adapting second-type sub-modules 120 with various designs. By providing a centralized point for data flow management, the global functional sub-module 130 may enable the architecture to support a flexible number of storage modules 200, allowing designers to integrate one, two, or multiple storage modules 200 based on application needs. In addition, the global functional sub-module 130 may also incorporate some global management features such as decoding, multiplexing, buffering, repair functions, global memory chip's refresh management, mode register settings, power network optimization, memory built-in self-test (MBIST), training, trimming, fusing or adjustment circuits (for one-time programming), programmable registers, and feature selections or functions. Furthermore, logical operations and computing units may be integrated to extend processing capabilities.

Detailedly, in some embodiments, the plurality of storage modules 200 may be designed to implement the storage function in a chiplet-based system. In other words, the plurality of storage modules 200 may be configured as chiplets. For example, the storage module 200 may be configured as memory core chiplets. All the storage modules 200 may have the same design and layout. In some embodiments, each storage module 200 may only include one chiplet. Alternatively, in some embodiments, the plurality of storage modules 200 may be designed to implement the storage function in a chip-based system. In other words, the plurality of storage modules 200 may be configured as chips. For example, the storage module 200 may be configured as memory core chips. All the storage modules 200 may have the same design and layout. In some embodiments, each storage module 200 may only include one chip.

For each storage module 200, the storage array 210 may be the core component of the storage module that physically stores data. The local interface sub-module 220 may serve as the interface between the storage array 210 and the global functional module 100. The local interface sub-module 220 may include circuitry to drive signals between the storage module 200 and the global functional module 100 and is designed to match the physical layer requirements of the first-type interface sub-module 110 of the global functional module 100. For example, the local interface sub-module 220 may contain the Input/Output protocols and electrical signal's transmission/reception (Tx/Rx) which may be able to be optimized for matching with the first-type interface sub-module 110 by adopting training procedures and compensations options. In some embodiments, the local interface sub-module 220 may be configured as physical layer that can interface with the first-type interface sub-module 110.

The local functional sub-module 230 may include basic logic circuits such as decoders, multiplexers, buffers, repair circuits, and refresh management circuitry. That is, the plurality of local functional sub-modules 230 may be configured as local periphery circuits. The local functional sub-module 230 may ensure that data stored in the storage array 210 is accessed, maintained, and, if necessary, corrected efficiently. Although these circuits are kept deliberately simple (to maintain area efficiency and lower design complexity), they are sufficient to perform the basic functions required for memory operation.

The design of the storage module 200 is highly scalable. Depending on customer requirements, the number of storage modules 200 integrated with the global functional module 100 can be adjusted. For instance, in some embodiments, multiple identical storage chiplets may be provided and integrated with a single global functional module 100. This flexibility facilitates rapid customization and enables a modular approach to semiconductor design, wherein validated storage module 200 can be reused in multiple products without re-design.

Detailedly, in some embodiments, the global functional module 100 may play a dual role. It can interface with both the plurality of storage modules 200 and the external logic module 300 to facilitate data access and processing.

Each first-type interface sub-module 110 may include a physical layer circuit that provides a standardized connection between the global functional module 100 and the corresponding local interface sub-module 220 of the storage module 200. In some embodiments, the first-type interface sub-module 110 may be configured as physical layer to interface with the local interface sub-module 220. All the first-type interface sub-modules 110 may share an identical design (layout) to ensure uniformity, signal integrity, and consistent electrical characteristics across the module. This homogeneity may simplify verification and testing and improve manufacturability.

In contrast to the first-type interface sub-module 110, the second-type sub-modules 120 may be designed to interface with external logic modules. The second-type sub-modules 120 may be configured as physical layer (with physical layer circuits) that have different designs (layouts) from one another, which allows them to interface with external logic modules from various designs. For example, one second-type sub-module 120 may be configured for interfacing with a controller for Double Data Rate 5th Generation Synchronous Dynamic Random-Access Memory (DDR5 SDRAM), another for interfacing with a controller for Low-Power Double Data Rate 5th Generation Synchronous Dynamic Random-Access Memory (LPDDR5 SDRAM), and yet another may support customized controllers. In the present embodiment, the external logic module 300-1 is a controller for DDR5 SDRAM and is interfaced with the leftmost second-type sub-module 120-1 in FIG. 1.

It should be noted that only one of the second-type sub-modules 120 (in the present embodiment is 120-1) is enabled for interfacing at any given time, while the others are disabled. The enablement may be controlled by a programming procedure that can be executed by system firmware or configuration software. This selective activation is particularly advantageous because it allows a single global functional module 100 to support multiple designs (standards or protocols) without incurring the cost and manufacturing complexity.

In some embodiments, the at least two second-type sub-modules 120 may be configured to compatible to standards comprising Joint Electron Device Engineering Council (JEDEC), Compute Express Link (CXL), Universal Chiplet Interconnect Express (UCIe), or Universal Serial Bus (USB).

This external interfacing using the second-type sub-module 120 is critical in ensuring that the semiconductor device 1A can communicate with other system components (e.g., the external logic module 300-1 or other applicable components), thereby enabling integration into larger system architectures.

The global functional sub-module 130 may play a crucial role as it serves as a bridge between the first-type interface sub-module 110 and the second-type sub-module 120. The global functional sub-module 130 may not only integrate and route data flows between these two physicals but also incorporate dynamic data flow management functions. This management capability is essential for handling variations in data traffic and ensuring that the storage module 200 remain scalable and the flexibility for accommodating external logic module with various designs. The global functional sub-module 130 may also provide additional processing and control functions that enhance the performance and reliability of the global functional module 100. In some embodiments, the global functional sub-module 130 may include decoder circuits, multiplexer circuits, buffer circuits, repair circuits, refresh management circuits, mode register setting circuits, power network management circuits, memory built-in self-test (MBIST) circuits, training circuits, and/or programmable circuits.

The decoder circuits may be used for address and data decoding. The multiplexer circuits may be used for routing data among various chiplets (e.g., the plurality of storage modules 200). The buffer circuits may be used to maintain signal integrity and drive external loads. The repair circuits may facilitate fault detection and error correction, while the refresh management circuits are essential for maintaining data integrity in dynamic memory systems. The mode register setting circuits may configure the operational mode of the global functional module 100, and the power network management circuits may optimize power distribution while minimizing power loss. The memory built-in self-test circuits may enable in-situ testing of memory functionality, the training circuits may help adapt to variations in process, voltage, and temperature conditions, and the programmable circuits can be configured for specialized functions based on customer requirements. The global functional sub-module 130 may offer a highly configurable and scalable logic peripheral that can be adapted to various external communication standards and protocols.

In addition, the global functional sub-module 130 may handle the majority of logic functions, allowing the plurality of storage modules 200 to be designed with only the essential logic circuits (e.g., the plurality of local functional sub-modules 230). Furthermore, by isolating the storage workload from the global functional module 100 to the storage module 200, the global functional module 100 can be manufactured using a more advanced process node than the storage module 200, enabling it to operate at a higher frequency while keeping costs manageable. For example, the operating frequency of the plurality of storage modules 200 may be lower than the operating frequency of the global functional module 100. The operating frequency may be increased within the global functional module 100 using the plurality of global functional sub-modules 130 or other applicable circuits.

The semiconductor device 1A permits multiple interface standards to coexist by providing several second-type sub-modules 120 with different designs (layouts). Through a programming procedure, a designer or system integrator can select the appropriate interface based on system requirements. The flexibility provided by this approach is particularly valuable in markets where multiple standards coexist and rapid adaptation to emerging protocols is required.

In some embodiments, the plurality of storage modules 200 may be configured as chiplets. In some embodiments, the global functional module 100 may be configured as a chip. In some embodiments, the global functional module 100 may be configured as a chiplet.

In some embodiments, the semiconductor device 1A may be designed to be implemented using advanced packaging techniques. The chiplets, both the plurality of storage modules 200 and the global functional module 100, can be manufactured separately and later integrated. The global functional module 100 and the plurality of storage modules 200 may be compatible with a range of packaging methods, including 2D integration, 2.5D integration, 3D integration, and/or 2.xD integration.

These packaging methods offer significant advantages, such as reducing the physical distance between chiplets, lowering communication latency, and increasing bandwidth. Furthermore, they allow for the integration of chiplets fabricated with different manufacturing process. For example, the global functional module 100 can be manufactured using advanced processes to enhance performance, while the storage module 200 can utilize mature, cost-effective processes. For another example, the global functional module 100 can be manufactured by logic processes and the storage module 200 can be manufactured by memory processes. This modular approach enables a “building-block” assembly of components, providing flexibility to tailor designs according to specific customer requirements and market demands.

The semiconductor device 1A may offer several advantages over conventional monolithic memory designs. By decoupling memory storage from logic functions, storage chiplets (e.g., the plurality of storage modules 200) can be reused across multiple products, reducing development time and costs. The modular chiplet-based design enables scalable integration, allowing the number of storage modules to be adjusted based on customer demand. Additionally, the system enhances flexibility by accommodating multiple external interfaces through the second-type sub-modules 120 of the global functional module 100. The design of the semiconductor device 1A can significantly reduce time-to-market, as reusable storage modules 200 eliminate the need for frequent full-chip redesigns, requiring only updates to the second-type sub-modules 120 of the global functional module 100 for new interfaces. This approach may also improve cost efficiency by lowering both non-recurring engineering and recurring manufacturing costs.

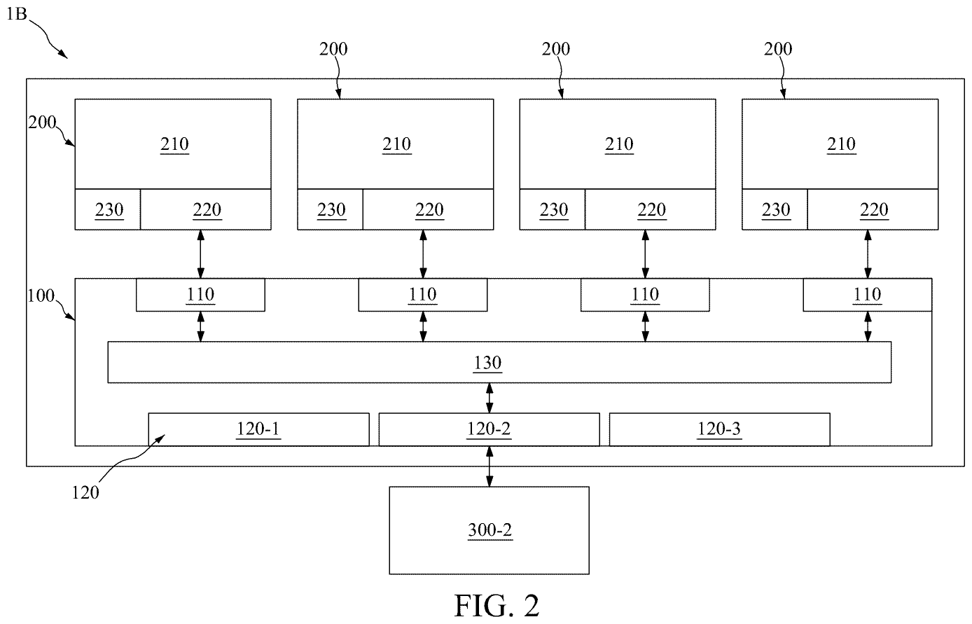

With reference to FIG. 2, the semiconductor device 1B may have an architecture similar to that illustrated in FIG. 1. The same or similar features in FIG. 2 as in FIG. 1 have been marked with similar reference numbers and duplicative descriptions have been omitted.

In the semiconductor device 1B, the external logic module 300-2 is a controller for LPDDR5 SDRAM and is interfaced with the middle second-type sub-module 120-2.

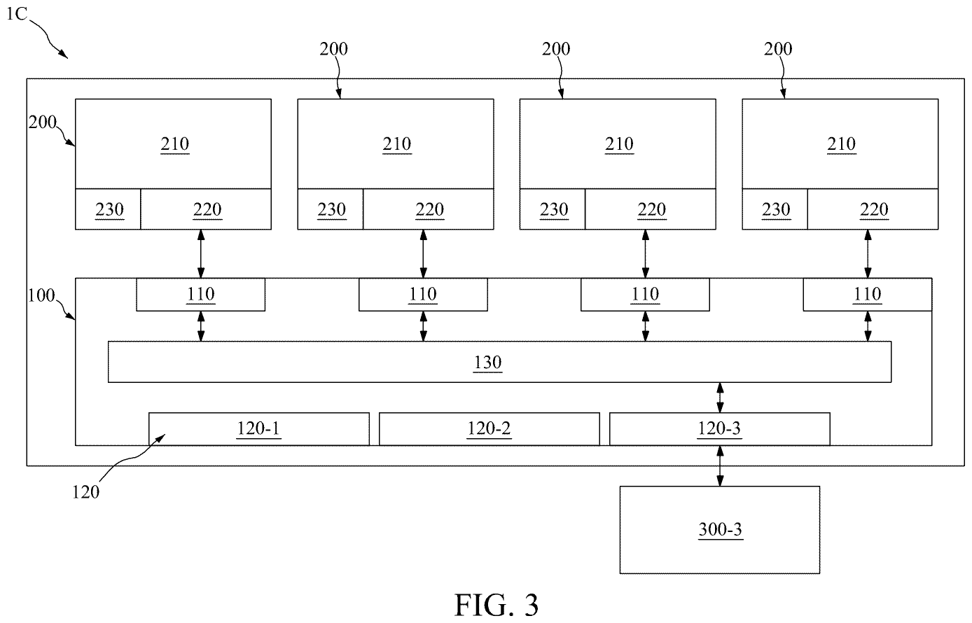

With reference to FIG. 3, the semiconductor device 1C may have an architecture similar to that illustrated in FIG. 1. The same or similar features in FIG. 3 as in FIG. 1 have been marked with similar reference numbers and duplicative descriptions have been omitted.

In the semiconductor device 1C, the external logic module 300-3 is a customized controller and is interfaced with the rightmost second-type sub-module 120-3.

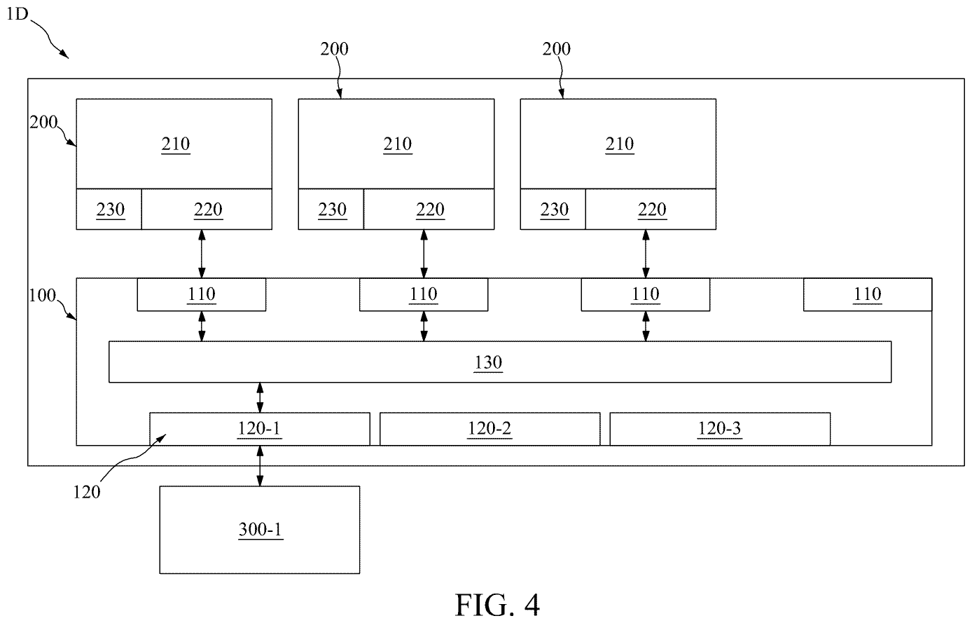

With reference to FIG. 4, the semiconductor device 1D may have an architecture similar to that illustrated in FIG. 1. The same or similar features in FIG. 4 as in FIG. 1 have been marked with similar reference numbers and duplicative descriptions have been omitted.

In the semiconductor device 1D, only three storage module 200 is connected to the first-type interface sub-module 110 of the global functional module 100. The rightmost first-type interface sub-module 110 is spared.

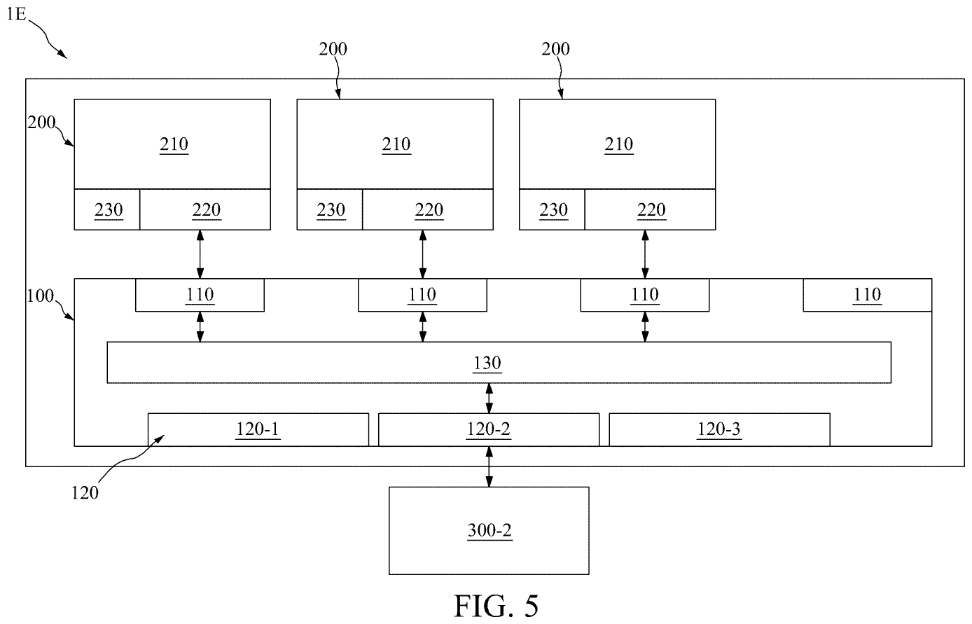

With reference to FIG. 5, the semiconductor device 1E may have an architecture similar to that illustrated in FIG. 4. The same or similar features in FIG. 5 as in FIG. 4 have been marked with similar reference numbers and duplicative descriptions have been omitted.

In the semiconductor device 1E, the external logic module 300-2 is a controller for LPDDR5 SDRAM and is interfaced with the middle second-type sub-module 120-2.

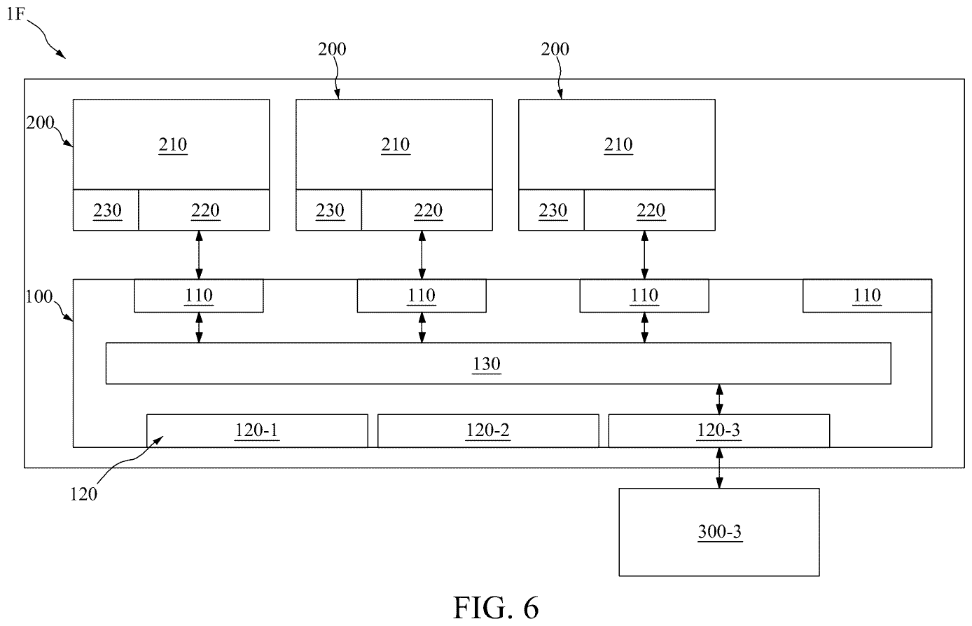

With reference to FIG. 6, the semiconductor device 1F may have an architecture similar to that illustrated in FIG. 4. The same or similar features in FIG. 6 as in FIG. 4 have been marked with similar reference numbers and duplicative descriptions have been omitted.

In the semiconductor device 1F, the external logic module 300-3 is a customized controller and is interfaced with the rightmost second-type sub-module 120-3.

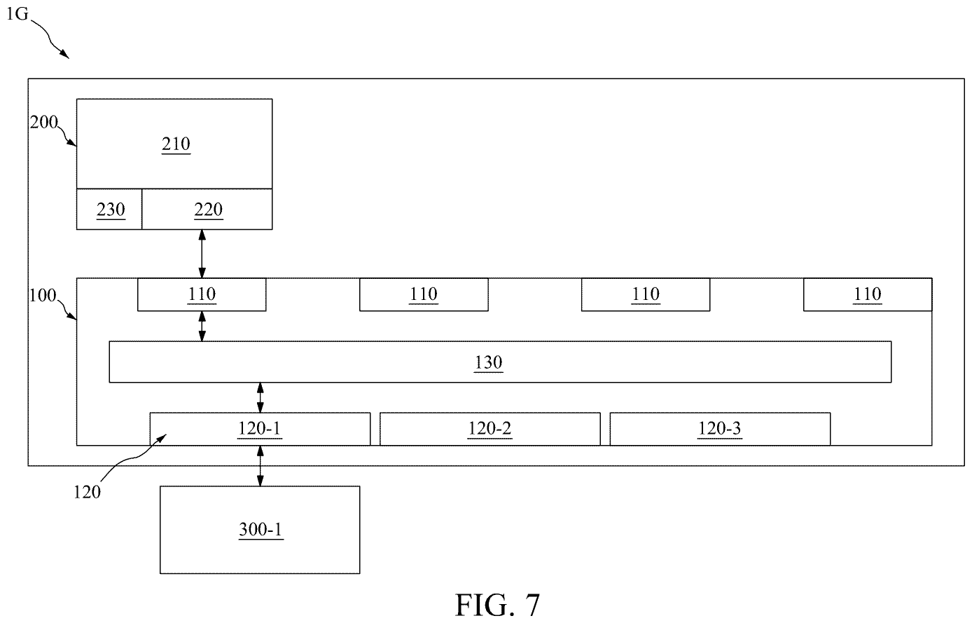

With reference to FIG. 7, the semiconductor device 1G may have an architecture similar to that illustrated in FIG. 1. The same or similar features in FIG. 7 as in FIG. 1 have been marked with similar reference numbers and duplicative descriptions have been omitted.

In the semiconductor device 1G, only three storage module 200 is connected to the first-type interface sub-module 110 of the global functional module 100. All other first-type interface sub-modules 110 are spared.

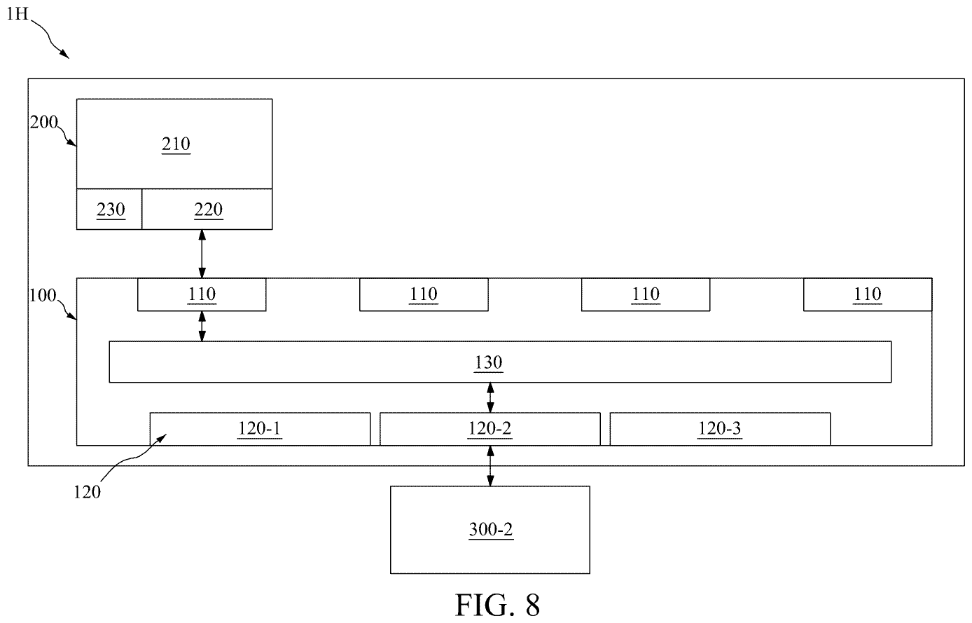

With reference to FIG. 8, the semiconductor device 1H may have an architecture similar to that illustrated in FIG. 7. The same or similar features in FIG. 8 as in FIG. 7 have been marked with similar reference numbers and duplicative descriptions have been omitted.

In the semiconductor device 1H, the external logic module 300-2 is a controller for LPDDR5 SDRAM and is interfaced with the middle second-type sub-module 120-2.

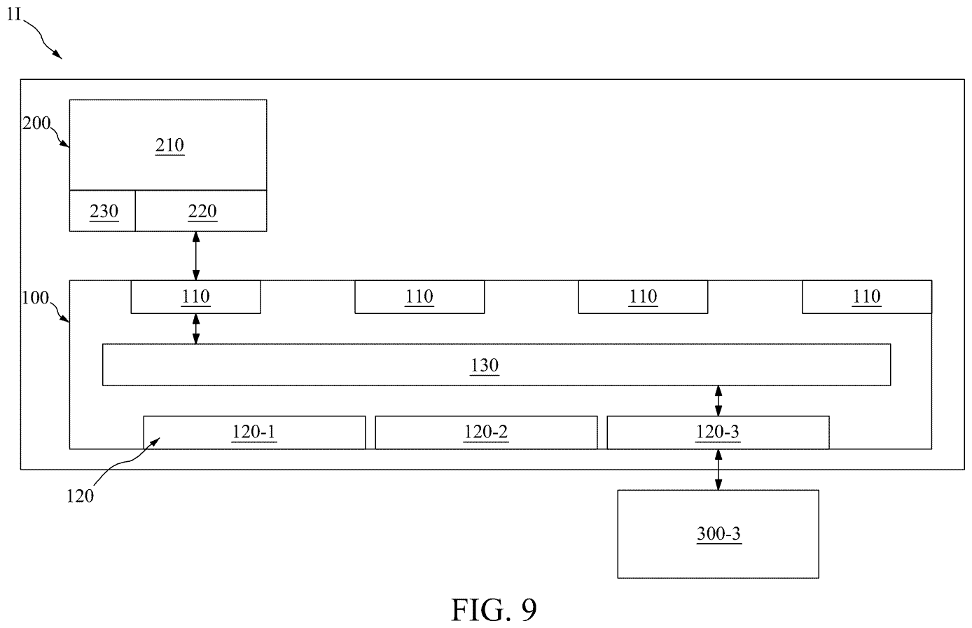

With reference to FIG. 9, the semiconductor device 1I may have an architecture similar to that illustrated in FIG. 7. The same or similar features in FIG. 9 as in FIG. 7 have been marked with similar reference numbers and duplicative descriptions have been omitted.

In the semiconductor device 1I, the external logic module 300-3 is a customized controller and is interfaced with the rightmost second-type sub-module 120-3.

In some embodiments, the first-type interface sub-module 110 and the second-type sub-modules 120 of the global functional module 100 may be configured as external physical layers. The first-type interface sub-module 110 may be dedicated to interfacing with the local interface sub-module 220 of the storage module 200, ensuring a robust electrical and signal connection for data transfer. In contrast, the second-type sub-modules 120-1, 120-2, or 120-3 may be tailored for interfacing with external logic modules 300-1, 300-2, or 300-3, respectively and correspondingly.

The global functional sub-module 130 of the global functional module 100 may play a crucial role as it serves as a bridge between the first-type interface sub-module 110 and the second-type sub-module 120. The global functional sub-module 130 may not only aggregate and route data flows between these two physical layers but also incorporate dynamic data flow management functions. This management capability is essential for handling variations in data traffic and ensuring that the storage module 200 remain scalable. By providing a centralized point for data flow management, the global functional sub-module 130 enables the architecture to support a flexible number of storage modules 200—allowing designers to integrate one, two, or multiple storage modules 200 based on application needs.

Furthermore, configuring the second-type sub-modules 120 into multiple variants, such as 120-1, 120-2, and 120-3, enables support for different types of external logic modules (e.g., 300-1, 300-2, and 300-3). This flexibility ensures that the semiconductor device can be tailored to a wide range of logic controllers, providing a high degree of customization without requiring a complete redesign of the global functional module 100.

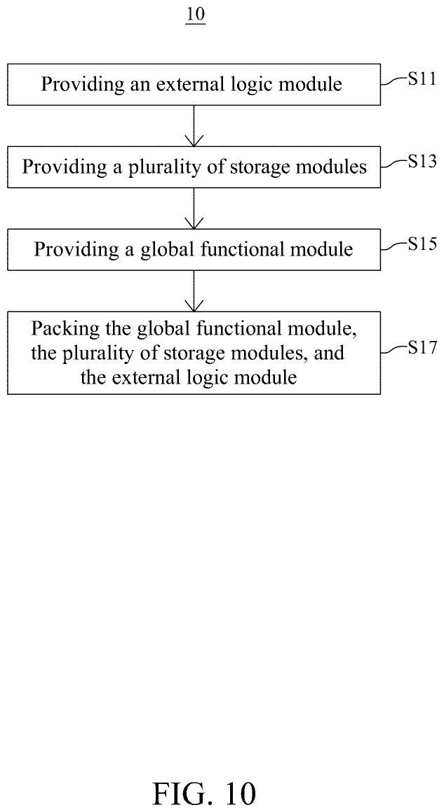

FIG. 10 illustrates, in a flowchart diagram form, a method 10 for fabricating a semiconductor device 1A in accordance with one embodiment of the present disclosure.

With reference to FIG. 10, at step S11, an external logic module may be provided.

In some embodiments, the external logic module (e.g., 300-1, 300-2, or 300-3) may be manufactured as a chip. In some embodiments, the external logic module may be manufactured as a chiplet. In some embodiments, the external logic module may be a controller for DDR5 SDRAM (e.g., 300-1), a controller for LPDDR5 SDRAM (300-2), or a customized controller (300-3).

With reference to FIG. 10, at step S13, a plurality of storage modules 200 may be provided.

In some embodiments, the plurality of storage modules 200 may be designed to implement the storage function in a chiplet-based or chip-based system. All the storage modules 200 may have the same design and layout. In some embodiments, each storage module may only include one chiplet or one chip. Each storage module 200 may include a storage array 210 including capacitors for actual data storage, a local interface sub-module 220 that provides the electrical/signal connection to the logic peripheral portion, and a plurality of local functional sub-modules 230 that provide essential functions (e.g., decoding, multiplexer, buffering, repair, and/or refresh management) for the storage array 210 and the local interface sub-module 220.

With reference to FIG. 10, at step S15, a global functional module 100 may be provided.

In some embodiments, the global functional module 100 may be responsible for handling external interfacing and system-level control. In some embodiments, the global functional module 100 may be manufactured as a chip. In some embodiments, the global functional module 100 may be manufactured as a chiplet. In some embodiments, the global functional module 100 may include a plurality of first-type interface sub-modules 110, at least two second-type sub-modules 120, and a global functional sub-module 130. The plurality of first-type interface sub-modules 110 may be designed with a uniform layout to interface reliably with the local interface sub-modules 220 of the plurality of storage modules 200, respectively and correspondingly. One of the at least two second-type sub-modules 120 may be configured to interface with the external logic module 300. The global functional sub-module 130 may manage data streaming between the first-type interface sub-module 110 and the second-type sub-module 120 and may provide additional processing functions for the global functional module 100 and the plurality of storage modules 200.

With reference to FIG. 5, at step S17, the global functional module 100, the plurality of storage modules 200, and the external logic module may be packaged.

In some embodiments, the packaging of the global functional module 100, the plurality of storage modules 200, and the external logic module may include 2D integration, 2.5D integration, 3D integration, 2.xD integration, and/or other applicable packaging techniques. In some embodiments, the interfacing between the global functional module 100 and the external logic module may be through the second-type sub-module 120 and corresponding physical layer of the external logic module. In some embodiments, the interfacing between the global functional module 100 and the plurality of storage modules 200 may be through the plurality of first-type interface sub-modules 110 of the global functional module 100 and the local interface sub-modules 220 of the plurality of storage modules 200.

In some embodiments, the global functional module 100, the plurality of storage modules 200, and the external logic module may be provided as chiplets. In some embodiments, the plurality of storage modules 200 may be provided as chiplets. The external logic module and the global functional module 100 may be provided as chips. In some embodiments, the plurality of storage modules 200, the external logic module, and the global functional module 100 may be provided as chips.

In some embodiments, the global functional module 100, the plurality of storage modules 200, and the external logic module may be mounted on a printed circuit board or substrate. In some embodiments, the global functional module 100, the plurality of storage modules 200, and the external logic module may be mounted on an interposer.

In some embodiments, the interfacing between the global functional module 100 and the external logic module or between the global functional module 100 and the storage module 200 may be achieved by wires, bumps, micro-bumps, or solder bumps.

In some embodiments, the interfacing between the global functional module 100 and the external logic module or between the global functional module 100 and the storage module 200 may be achieved by through-silicon vias.

One aspect of the present disclosure provides a global functional module including a plurality of first-type interface sub-modules; and at least two second-type sub-modules communicated with the plurality of first-type interface sub-modules.

Another aspect of the present disclosure provides a semiconductor device including a plurality of storage modules; a global functional module comprising a plurality of first-type interface sub-modules configured to interface with the plurality of storage modules, and at least two second-type sub-modules communicated with the plurality of first-type interface sub-modules and configured to interface with an external logic module.

Another aspect of the present disclosure provides a method for fabricating a semiconductor device including providing an external logic module; providing a plurality of storage modules; providing a global functional module comprising a plurality of first-type interface sub-modules, and at least two second-type sub-modules communicated with the plurality of first-type interface sub-modules; packaging the plurality of storage modules, the global functional module, and the external logic module. The plurality of first-type interface sub-modules interface with the plurality of storage modules. One of the at least two second-type sub-modules interfaces with the external logic module.

Due to the design of the semiconductor device in the present disclosure, the global functional module 100 and the storage module 200 integrate storage and logic functionalities in a modular and reconfigurable manner, providing flexibility in product design and reducing development time.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A global functional module, comprising:
a plurality of first-type interface sub-modules; and
at least two second-type sub-modules communicated with the plurality of first-type interface sub-modules.

2. The global functional module of claim 1, wherein the at least two second-type sub-modules are configured as physical layer circuits having different layouts.

3. The global functional module of claim 1, wherein the plurality of first-type interface sub-modules are configured as physical layer circuits with the same layout.

4. The global functional module of claim 2, wherein one of the at least two second-type sub-modules is configured to interface with an external logic module.

5. The global functional module of claim 4, wherein the external logic module is a controller for Double Data Rate 5th Generation Synchronous Dynamic Random-Access Memory (DDR5 SDRAM).

6. The global functional module of claim 4, wherein the external logic module is a controller for Low-Power Double Data Rate 5th Generation Synchronous Dynamic Random-Access Memory (LPDDR5 SDRAM).

7. The global functional module of claim 1, wherein the global functional module is configured as a chiplet.

8. The global functional module of claim 1, wherein the global functional module is configured as a chip.

9. The global functional module of claim 1, further comprising a global functional sub-module, wherein the at least two second-type sub-modules communicates with the plurality of first-type interface sub-modules through the global functional sub-module.

10. The global functional module of claim 9, wherein the global functional sub-module comprises a decoder circuit, a multiplexer circuit, a buffer circuit, a repair circuit, a refreshment management circuit, a mode register setting circuit, a power network optimization circuit, a memory built-in self-testing (MBIST) circuit, a training circuit, a trimming circuit, a fusing circuit, programmable register circuits, or a feature selection circuit.

11. The global functional module of claim 1, wherein the at least two second-type sub-modules are configured to compatible to standards comprising Joint Electron Device Engineering Council (JEDEC), Compute Express Link (CXL), Universal Chiplet Interconnect Express (UCIe), or Universal Serial Bus (USB).

12. The global functional module of claim 1, wherein only one of the at least two second-type sub-modules is enabled to interface with an external logic module, while the other second-type sub-modules remain disabled and non-functional for interfacing.
